(19) United States
(12) Patent Application Publication
(10) Pub. No.: US 2025/0334641 A1
(43) Pub. Date: Oct. 30, 2025

(54) ADJUSTING FOR AN ALTERNATING SIGNAL IN ELECTROCHEMICAL IMPENDANCE SPECTROSCOPY

(71) Applicant: Analog Devices International Unlimited Company, Limerick (IE)

(72) Inventors: Leon Alexander Loopik, Delft (NL); Marc Zwalua, Müchen (DE); Hemant Kumar, Munich (DE); Colin G. Lyden, Baltimore (IE)

(21) Appl. No.: 19/181,242

(22) Filed: Apr. 16, 2025

Related U.S. Application Data
(60) Provisional application No. 63/636,204, filed on Apr. 19, 2024.

(51) Int. Cl. G01R 31/389; G01R 31/36

(52) U.S. Cl. CPC G01R 31/389; G01R 31/3648

(57) ABSTRACT

An electrochemical impedance spectroscopy (EIS) measurement system to adjust for an alternating current (AC) signal of an electrochemical cell in an energy storage system can include a current measurement device and a voltage measurement device. The EIS measurement system can also include processing circuitry, which can be coupled to the current measurement device and the voltage measurement device and which can be configured to determine an EIS impedance at a specified EIS frequency, which can include performing a first EIS impedance measurement using an EIS excitation signal which can have a first phase to produce a first intermediate EIS impedance value, performing a second EIS impedance measurement using an EIS excitation signal which can have a second phase, where the first phase can differ from the second phase, to produce a second intermediate EIS impedance value, and determining the EIS impedance including by determining a central tendency of the first intermediate EIS impedance value and the second intermediate EIS impedance value.

### CLAIM OF PRIORITY

This patent application claims the benefit of priority of Loopik et al., U.S. Provisional Patent Application Ser. 63/636,204, entitled “CURRENT PROFILE DISTORTION CORRECTION FOR ELECTRICAL IMPEDANCE SPECTROSCOPY,” filed on Apr. 19, 2024 (Attorney Docket No. 3867.C49PRV), which is hereby incorporated by reference herein in its entirety.

### TECHNICAL FIELD

The present disclosure relates to electronics, and more particularly, but not by way of limitation, to a battery monitoring system that can determine the complex impedance of battery cells or other electrochemical energy storage systems.

### BACKGROUND

Modern systems can use electrochemical cells, such as energy storage systems and electrolysis systems. Energy storage systems can include batteries or fuel cells, and can be a main power source or an auxiliary power source. Electrolysis systems can include electrolysis cells, such as for driving a chemical reaction using electrical energy. Examples of such modern systems can include consumer electronics, industrial electronics, passenger cars, industrial trucks, and industrial processing plants. Monitoring a parameter of a cell, such as the state of charge (SoC) or the state of health (SoH), can help ensure reliable operation of the system and avoid unnecessary damage to the cell, such as due to overheating.

### SUMMARY

In an example, an electrochemical impedance spectroscopy (EIS) measurement system to adjust for a change in a direct current (DC) voltage value of an electrochemical cell in an energy storage system can include a current measurement device, which can be arranged for measuring a current through the electrochemical cell. The EIS measurement system can also include a voltage measurement device, which can be arranged to be coupled across the electrochemical cell, for measuring a voltage across the electrochemical cell. The EIS measurement system can also include processing circuitry, which can be coupled to the current measurement device and the voltage measurement device and which can be configured to determine a representation of the DC voltage across the electrochemical cell, where the representation of the DC voltage across the electrochemical cell can indicate that the DC voltage across the electrochemical cell can be changing. The processing circuitry can also be configured to determine an EIS voltage at a specified EIS frequency using the representation of the DC voltage across the electrochemical cell and the measured voltage across the electrochemical cell.

In an example, an electrochemical impedance spectroscopy (EIS) measurement system to adjust for an alternating current (AC) signal of an electrochemical cell in an energy storage system can include a current measurement device, which can be arranged for measuring a current through the electrochemical cell. The EIS measurement system can also include a voltage measurement device, which can be arranged to be coupled across the electrochemical cell, for measuring a voltage across the electrochemical cell. The EIS measurement system can also include processing circuitry, which can be coupled to the current measurement device and the voltage measurement device and which can be configured to determine an EIS impedance at a specified EIS frequency, which can include performing a first EIS impedance measurement using an EIS excitation signal which can have a first phase to produce a first intermediate EIS impedance value, performing a second EIS impedance measurement using an EIS excitation signal which can have a second phase, where the first phase can differ from the second phase, to produce a second intermediate EIS impedance value, and determining the EIS impedance including by determining a central tendency of the first intermediate EIS impedance value and the second intermediate EIS impedance value.

### BRIEF DESCRIPTION OF THE DRAWINGS

In the drawings, which may not be drawn to scale, like numerals may describe substantially similar components throughout one or more of the views. Like numerals having different letter suffixes may represent different instances of substantially similar components. The drawings illustrate generally, by way of example but not by way of limitation.

FIG. 1 is a schematic drawing of an example of portions of a battery monitoring system circuit.

FIG. 2 is a schematic drawing of an example of portions of a battery monitoring system circuit.

FIG. 3A shows an example of a graph in time of the voltage across an electrochemical cell in DC steady state receiving an EIS excitation signal.

FIG. 3B shows an example of a graph in time of the voltage across an electrochemical cell receiving a charging signal in addition to an EIS excitation signal.

FIG. 4A shows an example of the total harmonic distortion in an EIS voltage measurement.

FIG. 4B shows an example of the total harmonic distortion in an EIS voltage measurement.

FIG. 5 shows an example of portions of a method for operating an EIS measurement system.

FIG. 6A shows an example of a graph in time showing laboratory recorded electrochemical cell charging current.

FIG. 6B shows an example of a frequency plot of the charging current of FIG. 6A.

FIG. 7A shows an example of a graph in time showing laboratory recorded electrochemical cell charging current.

FIG. 7B shows an example of a frequency plot of the charging current of FIG. 7A.

FIG. 8 shows a graph of an example of an error caused by a disturbance signal.

FIG. 9 shows an example of portions of a method for operating an EIS measurement system.

FIG. 10 shows an example of portions of a operational flow chart of an EIS measurement system.

FIG. 11 is a block diagram of an example of portions of a machine upon which one or more portions of the present disclosure may be implemented.

### DETAILED DESCRIPTION

Battery monitoring systems (BMS), such as an automotive BMS, can be used to keep track of state of charge (SoC) or state of health (SoH) of battery cells (e.g., battery cell stacks, large battery cell stacks used in electric vehicles). BMS can also be used to balance the cells while charging to, such as to help improve lifespan or total energy stored. The BMS system can partially or completely bypass a cell or cell group, such as based on the indicated SoC or SoH. A BMS can also measure the temperature of the cells using several temperature sensors that are mounted to the outside of the cells.

In an approach, SoC can be determined by measuring the cell voltage. However, this may be effective only if the cell voltage is a well-defined and a sufficiently sensitive function of SoC. This may not be the case for some electrochemical cells. Additionally, it may use a voltage measurements that measures absolute voltage (e.g., voltage without a zero offset) at a specified precision, which may be benefitted by using a precision reference, such as can increase a cost or area of the circuit.

In an approach, temperature can be measured using sensors that are external to the cells. However, this can provide an inaccurate representation of the internal cell temperature, such as during times of large cell current regimes (hard accelerating, hard braking).

One approach to estimate the SoC, SoH, or temperature is electrochemical impedance spectroscopy (EIS). EIS can be used to determine the complex impedance of a cell or group of cells in an energy storage system. The energy storage system may include an arrangement of battery or fuel cells. The complex impedance of a cell or group of cells can be determined at a single frequency or at multiple frequencies. The determined complex impedance of the cell or group of cells can be used to obtain information about the SoC, SoH, or temperature of the cell or group of cells. The determined complex impedance can be used to estimate the charge level of the cell or group of cells. The determined complex impedance can be used to estimate the internal temperature of the battery. Estimation of the internal temperature of the battery can be more useful than measuring the external temperature of the battery, which may not accurately reflect internal temperature, which can result in overheating of the battery. The determined complex impedance can be used to estimate the available capacity of the cell or group of cells relative to new. A complex impedance at a single frequency may be useful for determining one or more measures of SoC or SoH. A complex impedance at multiple frequencies may be useful for determining one or more measures of SoC or SoH.

The present inventors have recognized, among other things, that the need for accurate and predictive battery monitoring systems (BMS) has grown with the interest in increasing use-time, range, and performance of the systems and devices using energy storage systems. For example, the more that a battery is discharged (e.g., to a lower SoC) or the more aggressively a battery is used, the more likely the battery is to be damaged if not effectively monitored.

The present inventors have recognized, among other things, that an EIS measurement may be the most accurate when an electrochemical cell is in a steady state (e.g., not charging or discharging, without a direct current (DC) current). The accuracy or precision of an EIS measurement can be impacted when the electrochemical cell is powering a load or being charged. This can limit the accuracy of an EIS measurement during times when high accuracy can be desired, such as during vehicle operation or speed charging. Accurate EIS measurement can help to prevent or reduce overheating, over-charging, under-charging, or over-discharging. This can make adjusting an EIS measurement to consider a non-steady state condition of a battery desirable, such as to increase an accuracy of an EIS measurement made during charging or discharging.

The present inventors have also recognized, among other things, that an EIS measurement may be affected by an alternating current (AC) signal in the electrochemical cell. For example, an AC signal can be produced due at least in part to charging of the electrochemical cell (e.g., the charger may output an AC signal (e.g., noise) in addition to a DC charging signal) or discharging of the electrochemical cell (e.g., switching in a motor controller can produce AC signals). Accordingly, it can be desirable to reduce or otherwise tailor an effect that an AC signal has on an EIS measurement.

The present disclosure relates to an EIS measurement system that can determine the complex impedance associated with a cell or group of cells in an electrochemical cell system (e.g., energy storage system, electrolysis system).

A complex current or voltage may be associated with a corresponding frequency value, an amplitude value, and a phase value. The frequency value may represent the frequency at which a periodic impedance test signal repeats itself. Frequency may be measured in the number of times the signal repeats itself per second, or Hertz (Hz). The amplitude value may represent the size or magnitude of the current or voltage signal. The amplitude value may be measured in Amps (A) for current and Volts (V) for voltage. The amplitude value may be determined by the peak of the periodic signal, or it may be determined by some other method, such as taking the square root of the mean of the signal squared (RMS). Using an amplitude measured in RMS units may be helpful in determining power dissipation. The phase value may be determined by measuring the position of one signal in time relative to the position of another signal in time. For example, the positive-going zero crossing of a voltage signal may be measured relative to the positive-going zero crossing of a current signal. If the voltage and current signals are aligned in time, the signals may be defined as being in phase, and the phase value may be defined as 0 degrees. If the voltage signal may be peaking when the current signal is at its positive crossing zero, this may be defined as the voltage signal leading the current signal by 90 degrees.

A complex impedance value may have a magnitude and a phase value at a given frequency. A complex impedance value may also be defined in terms of a real component and an imaginary component at a given frequency. A complex impedance value may be determined for a circuit element or a group of circuit elements by dividing a complex voltage value across the circuit element or elements by a complex current value through the circuit element or elements:

$$Z = \frac{V}{I}$$

where Z represents the complex impedance, V represents the complex voltage, and I represents the complex current. The magnitude of the complex impedance value may represent the ratio of the magnitude of the voltage to the magnitude of the current, and the phase of the complex impedance value may represent the difference in between the phase of the complex voltage and the phase of the complex current. Because the phase value of the complex impedance represents the relative difference between the phases of the voltage and current, an absolute measure of phase relative to a specific point in time is not required.

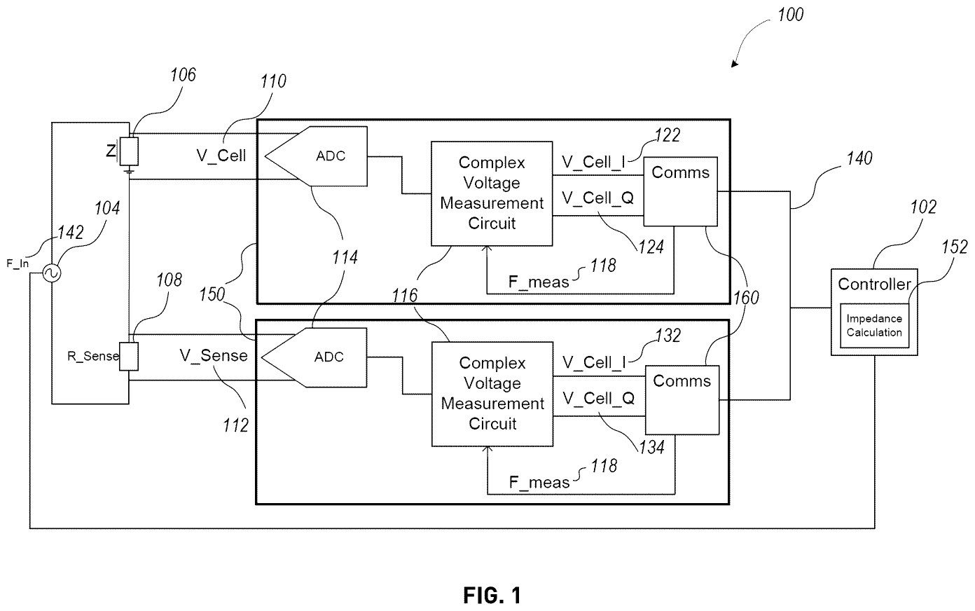

FIG. 1 is a schematic diagram of an example of portions of a BMS circuit 100 (e.g., an EIS measurement system) for testing an energy storage cell 106, such as can comprise or be included in an energy storage system. In the example of FIG. 1, the BMS circuit 100 can include a BMS controller 102, a test signal generation circuit 104, a test resistor 108, one or more complex voltage processing circuits 150 for processing complex voltages, and a communication bus 140.

The BMS controller 102 may include an integrated circuit (IC), a field-programmable gate array (FPGA), or any other device capable of executing computer code. The BMS controller 102 may include flash memory, random access memory, and any other type of memory storage device. The BMS controller 102 may be a portion of another circuit, or the tasks of the BMS may be handled by performing operations using programmed or stored instructions and a computer or controller. The BMS may perform operations in addition to battery monitoring. The BMS controller 102 may be connected to one or more test signal generation circuits 104 and one or more complex voltage processing circuits 150. The BMS controller 102 may communicate with the one or more test signal generation circuits 104 or the one or more complex voltage processing circuits 150 using one or more communication buses 140 or another type of communication system. The BMS controller 102 may include an impedance calculation circuit 152, for determining the impedance of one or more energy storage cells 106.

The impedance calculation circuit 152 may determine the complex impedance of an energy storage cell 106 by dividing the complex voltage across the energy storage cell 106 by the complex current through the energy storage cell 106—calculating complex conductance (inverse of complex impedance) should be understood in this document to be equivalent to calculating complex impedance and is addressed in this document by using the term complex impedance to refer generally to a complex impedance or its inverse complex conductance. Additionally, the impedance calculation circuit 152 may determine the complex impedance of an energy storage cell 106 by accepting as inputs two complex voltage values, and one corresponding test resistor 108 resistance value R_Sense, across which one of the voltage measurements is made. The test resistor 108 resistance value R_Sense may be measured or calibrated initially or periodically and not taken as an input. In an example, the BMS controller 102 may calculate a value indicative of the complex impedance of the energy storage cell 106, such as the inverse of the impedance. In an example, the BMS controller 102 may calculate of value indicative of the complex impedance of the energy storage cell 106, and compare this calculated indicative value to the value of a similar battery, or the battery currently being measured, such as when the battery was newly manufactured, newly installed, and/or fully charged.

The test signal generation circuit 104 may include a current generator, a voltage generator, or any other circuit capable of producing a varying or periodic test or “excitation” signal. The test signal generation circuit 104 may be connected to the BMS controller 102 via a communication bus or another wired or wireless communication system. The test signal generation circuit 104 may receive a test signal frequency input 142 from the BMS controller 102. The test signal generation circuit 104 may be connected in series with a device under test, such as an energy storage cell 106, or an arrangement of energy storage cells. The test signal generation circuit 104 may be capable of producing a time-varying or periodic current or voltage signal at a specified frequency, such as the test signal frequency input 142. The specified frequency may be specifiable, adjustable, or variable, such as being continuously variable across a certain range, or capable of producing one of a number of discrete frequencies. The test signal generation circuit 104 may be connected to one or more charging circuits, one or more rebalancing circuits, one or more load resistors, or one or more operating loads such as a traction motor or a regenerative braking system to provide the desired power source or power sink to generate the voltage or current signal.

The energy storage cell 106 may be a battery cell a fuel cell, or some other type of energy storage cell. The energy storage cell 106 may have an internal impedance, Z, and a voltage V_Cell 110. The internal impedance may be a complex value with a magnitude and phase component. The internal impedance may vary based upon the frequency at which Z is measured and upon the SoC and SoH of the energy storage cell 106. A complex voltage processing circuit 150 may be connected across the energy storage cell 106

The test resistor 108 may be a dedicated resistive element having a specified, measured, or calibrated resistance. The test resistor 108 may be connected in series with an energy storage system. The test resistor 108 may be connected in series with the test signal generation circuit 104. The test resistor 108 may be used to generate a voltage, V_Sense 112, corresponding to the current through the test resistor 108 and therefore through the energy storage cell or system. Converting the energy storage cell or system current to a voltage may allow the voltage and the respective current to be measured by a voltage measurement circuit. A complex voltage processing circuit 150 may be connected across the test resistor 108.

The one or more complex voltage processing circuits 150 may include a digital sampling circuit 114, a complex voltage measurement circuit 116, a communications circuit 160, and additional digital and/or analog signal processing circuitry. The one or more complex voltage processing circuits 150 may be connected across a circuit element, such as an energy storage cell 106 or a test resistor 108, to measure the voltage across the circuit element. The one or more complex voltage processing circuits 150 may take the voltage across the connected circuit element as an input. The one or more complex voltage processing circuits 150 may also take a measurement frequency 118 as an input. The complex voltage processing circuits 150 may produce as outputs a complex voltage measurement, such as including an amplitude and a phase or a real component and an imaginary component, at a specified frequency.

The complex voltage processing circuit 150 connected across the energy storage cell 106 may produce as outputs a real component of the cell voltage V_Cell_I 122, and an imaginary component of the cell voltage V_Cell_Q 124. The complex voltage processing circuit 150 connected across the test resistor 108 may be similar to the voltage processing circuit 150 connected across the energy storage cell 106, or may differ in one or more aspects. The complex voltage processing circuit 150 connected across the test resistor 108 may produce as outputs a real component of the test resistor voltage V_Sense_I 132, and an imaginary component of the test resistor voltage V_Sense_Q 134. In an example, the one or more of the complex voltage processing circuits 150 produce outputs corresponding to the amplitude and phase of a voltage value.

The communications circuit 160 may be connected to the controller 102 by the communications bus 140. The communications circuit 160 may process input signals from the controller 102 and distribute various portions of the input signals to the other circuit components. The communications circuit 160 may process output signals from the complex voltage processing circuits 150 that are sent to the controller 102. The communications circuit 160 may convert an analog signal to a digital signal, or a digital signal to an analog signal. The communications circuit 160 may convert a digitized signal of one type or standard to a digitized signal of another type or standard. The communications circuit 160 may perform buffering or storage tasks for the input and output information.

The complex voltage measurement circuit 116 may accept as inputs a digitized representation of a voltage, and a measurement frequency 118, and produce as outputs values indicative of the complex voltage of the incoming digitized voltage representation. The complex voltage measurement circuit 116 may also accept as inputs a timing indication upon which to base the phase measurement. The timing indication may be included in the measurement frequency 118 input. In an example, the complex voltage measurement circuit 116 generates an output corresponding to the relative timing of its phase measurement for use by the impedance calculation circuit 152 in determining the correct phase of the measurement. The frequencies at which complex impedance of one or more of the energy storage cells 106 are measured or calculated may span a large range such as from 0.01 Hz to 100 kHz, 0.1 Hz to 10 kHz, 10 Hz to 8 kHz, or 3 kHz to 6 kHz.

From the measurement frequency 118 and timing indication, the complex voltage measurement circuit 116 may determine the complex impedance by various methods, such as can include projecting the incoming digitized voltage representation upon orthogonal reference signals, such as two periodic signals that are 90 degrees out of phase, such as a “Sine” and a “Cosine” signal. The portion of the incoming digitized voltage representation that is in phase with the “Sine” signal may be referred to as the real component and the portion in phase with the “Cosine” signal may be referred to as the imaginary component. The complex voltage may be represented as the sum of the real component with the imaginary component multiplied by the imaginary number “i”:

$$Complex Voltage = Real Component + Imaginary Component * i$$

$$i = \sqrt[2]{- 1}$$

The complex voltage may be transformed to a representation in terms of amplitude and phase:

$$Complex Voltage = Amplitude ∠ Phase$$

$$Amplitude = \sqrt[2]{{( Real Component )}^{2} + {( Imaginary Component )}^{2}}$$

$$Phase = ArcTan ( \frac{Imaginary Component}{Real Component} )$$

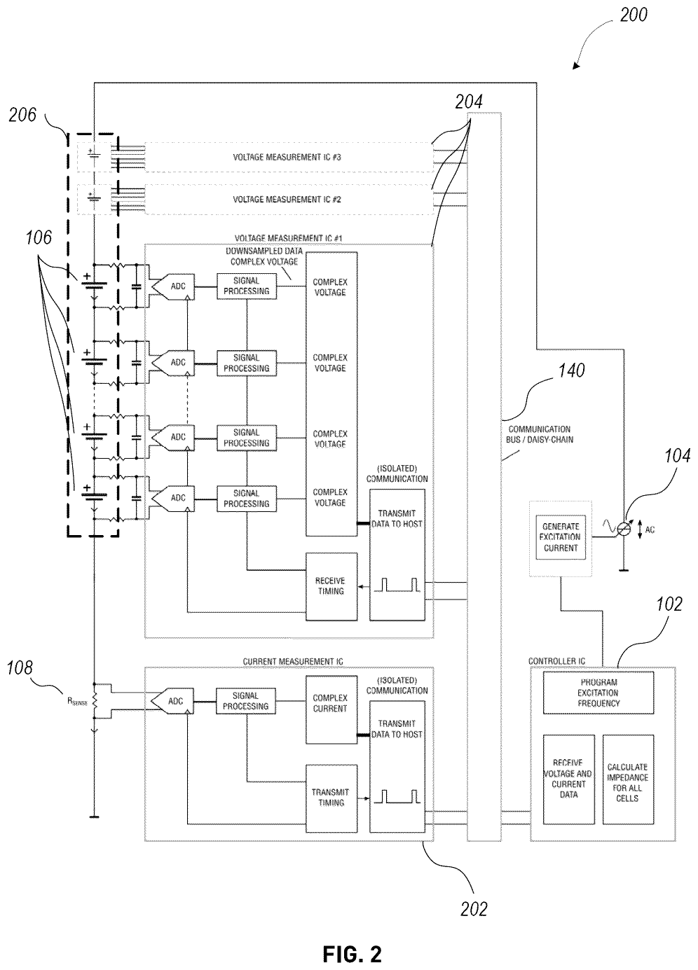

FIG. 2 is a schematic diagram of an example of portions of a BMS circuit 200 (e.g., an EIS measurement system). In the example of FIG. 2, the BMS circuit 200 contains a BMS controller 102, a test signal generation circuit 104, an arrangement of cells comprising an energy storage system 206, a current measurement IC 202 located on an integrated circuit, one or more voltage measurement ICs 204 located on respective integrated circuits, and a communication bus 140. In an example, the BMS circuit 200 is used in an electric or hybrid vehicle, such as in the automotive industry.

The BMS controller 102 can receive voltage and current measurements from the various ICs and then can calculate the impedance, or a value indicative of impedance, of individual energy storage cell 106 or groups of energy storage cells.

The energy storage system 206 may include one or more energy storage cell 106. The one or more energy storage cell 106 may be similar in design and construction such as chemistry, voltage, and capacity, or they may differ in one or more ways The one or more energy storage cell 106 may be connected in series so that their voltages add together. The one or more energy storage cell 106 may also be connected in parallel so that their capacities add together. In an example, there are a number of groups of 2, 3, 4, or 5 parallel connected cells with the groups connected in series. In an example, there are a number of cells all connected in series. In an example, the number of series-connected cells is between 50 and 300, between 100 and 250, between 150 and 200, or, in an illustrative example, 180.

In an example, each series-connected cell has a voltage value, a current value, and a complex impedance value. In an example, the current value is the same for all of the cells because they are series-connected, and therefore, the current can be measured at one point in the energy storage system 206 to determine the current through all of the one or more energy storage cell 106. This allows the BMS controller 102 to determine the complex impedance of each of the energy storage cell 106 individually by collecting a single complex current value for the battery arrangement from the current measurement IC and a voltage measurement from one of the one or more voltage measurement ICs 204 for each of the energy storage cell 106. This may result in fewer signal messages being transmitted over the communication bus 140 than would be used to calculate complex impedance for each of the cells in other ways. In an example, the voltage one or more voltage measurement ICs 204 and the current measurement IC do not share data about their respective measured value, but instead, send data to the BMS controller 102 which the BMS controller 102 can use to calculate complex cell impedances.

The current measurement IC 202 measures the complex current flowing through the energy storage system 206 or a portion of the energy storage system 206. In an example, the current measurement IC 202 determines the complex current flowing through the measured portion of the energy storage system 206 by measuring the voltage across a test resistor 108, and then using a specified, measured, or calibrated value of the test resistor 108 to determine the current. In an example, the current measurement IC 202 passes the measured complex voltage to another circuit which determines the complex current using the specified, measured, or calibrated value of the test resistor 108. The current measurement IC 202 is connected to the BMS controller 102 by a bus 140 for communication.

The one or more voltage measurement ICs 204 can measure the complex voltage across one or more of the energy storage cell 106. The one or more voltage measurement ICs 204 can be connected to the BMS controller 102 by a communication bus 140 for communication. In an example each of the one or more voltage measurement ICs 204 can measure the complex voltage of between 5 and 30 cells, between 10 and 20 cells, between 15 and 20 cells, or 18 cells. In an example, the number of cells that each voltage measurement IC 204 measures is limited to keep the maximum differential voltage between any components on the integrated circuit below a desired value, such as 15 volts, 30 volts, 45 volts, 60 volts, 75 volts, 100 volts, or 150 volts. The one or more voltage measurement ICs 204 may measure the voltage of each of the connected cells individually by coupling a voltage measurement circuit across each cell, or the one or more voltage measurement ICs 204 may measure the voltage of one or more arrangements of cells, such as including series and/or parallel arrangements.

The communication bus 140 may transmit digital or analog signals. In an example, the communication bus 140 is a digital serial bus carrying data between various circuits. In an example, the communication bus 140 can be a linear topology, a daisy-chained topology, or a hub-and-spoke (star) topology. In an example, the communication bus 140 is a DC isolated bus that uses at least one of capacitive-coupling or inductive-coupling to connect ICs operating at different voltage levels due to their connection to the energy storage system 206 at differing points. In an example, the communication bus 140 can include an electrically insulated communication system, such as a fiberoptic communication system. A transformer may be used at various points along the communication bus 140 to provide DC isolation and inductive-coupling. A capacitor may be used at various points along the communication bus 140 to provide DC isolation and capacitive coupling. In an example, the communication bus 140 may have a limited bandwidth to conserve resources due to the need for DC isolation or voltage level hopping circuitry between the ICs. In an example, the communication bus 140 may be able to operate without requiring a universally shared clock signal between all of the connected circuits. In an example, the current measurement IC 202 does share a clock signal with the BMS controller 102, but one or more of the voltage measurement ICs 204 do not share a clock signal with the BMS controller 102. In an example, the circuits have their own local clocks that are asynchronous with one another. The system may avoid distributing a clock signal between all of the ICs because of the difficulty and expense or power consumption of distributing a clock signal between ICs at different DC voltage levels.

The current measurement IC 202 and the one or more voltage measurement ICs 204 may make the complex voltage measurements in a similar fashion to the circuitry of FIG. 1 (e.g., one or more of the voltage measurement ICs 204 or the current measurement IC 202 can be configured similarly to the complex voltage processing circuits 150). The current measurement IC 202 and the one or more voltage measurement ICs 204 may receive a signal indicating the desired test frequency of the BMS controller 102 or the actual output frequency of the test current generated by the test signal generation circuit 104. In an example, the current measurement IC 202 determines the test frequency by analyzing the voltage it measures across the test resistor 108, and sends this determined frequency to the one or more voltage measurement ICs 204. The current measurement IC 202 and the one or more voltage measurement ICs 204 may receive a timing signal to help in determining the phase of the complex voltage measurement. In an example, the receipt time of the signal indicating the frequency may be indicative of the timing signal, such as representing the timing of a positive-going zero crossing of the test current.

The BMS circuit 100 and the BMS circuit 200 discussed above can show an example of an EIS measurement system. However, the systems and methods of the present disclosure are not limited to the circuits disclosed, and can be implemented on any system capable of performing the claimed functions. Additionally, the present disclosure is believed to apply to all electrochemical cells, including energy storage cells and cells that consume energy (e.g., an electrolyssi cell).

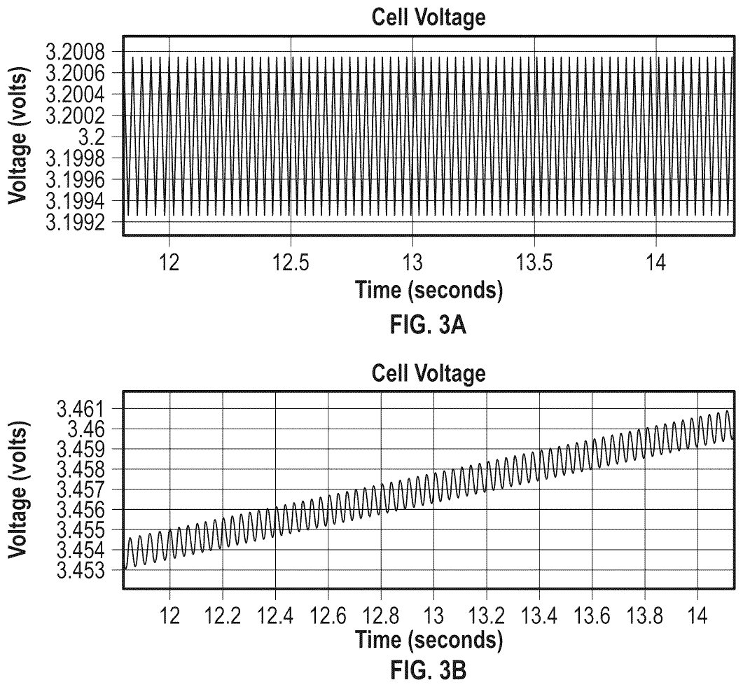

FIG. 3A shows an example of a graph in time of the voltage across an electrochemical cell in DC steady state receiving an EIS excitation signal. FIG. 3A shows a theoretical example. The electrochemical cell of FIG. 3A can be in a relaxed state, such as can occur a period of time after charging and discharging signals end (e.g., 5 minutes after the last charging or discharging signal). In the example of FIG. 3A, the EIS excitation signal can be the only signal having an effect on the battery voltage and/or current. An electrochemical cell can be in a DC steady state when the linear fit of cell voltage or current has substantially zero slope or a slope below a specified threshold (e.g., when the linear fit is applied over a length of time that exceeds the period of the EIS excitation signal, such as can include five periods of the EIS excitation signal, 10 periods of the EIS excitation signal, or 100 periods of the EIS excitation signal). An electrochemical cell can be in a DC steady state when the energy stored in the battery is substantially constant over time (e.g., when the energy stored is considered over a length of time that exceeds the period of the EIS excitation signal, such as can include five periods of the EIS excitation signal, 10 periods of the EIS excitation signal, or 100 periods of the EIS excitation signal).

FIG. 3B shows an example of a graph in time of the voltage across an electrochemical cell receiving a charging signal in addition to an EIS excitation signal. FIG. 3B shows a theoretical example. The electrochemical cell of FIG. 3B can be in a charging state, such as due to receiving a charging signal. In the example of FIG. 3B, the charging signal in addition to the EIS excitation signal can have an effect on the battery voltage and/or current. An electrochemical cell may not be in a DC steady state when the linear fit of cell voltage or current has a positive or negative slope, or a slope above a specified threshold. An electrochemical cell may not be in a DC steady state when the energy stored in the battery is changing over time. FIG. 3A and FIG. 3B show examples of voltage waveforms, but similar waveforms can exist for current.

The voltage measurement ICs 204 and/or the current measurement IC 202 determine an AC voltage using one or more techniques. For example, a complex voltage or current value at a specified EIS frequency can be determined by projecting a measured waveform onto a function (e.g., a sinusoid) of the specified EIS frequency. This projection can be done in the digital domain, the analog domain, or both. For example, a number of digital samples can be taken, and the digital samples can be projected onto the specified function to determine an amplitude of the specified function present (e.g., by integrating a product of the digital samples and the specified function). In an approach, a transform (e.g., an integral transform, a Fourier Transform) of the digital samples can be determined, and the amplitude of the signal at the specified EIS frequency can be determined.

In one or more approaches, a change in the operating point of the battery (e.g., a non-steady-state condition) can affect the determined amplitude at the specified EIS frequency, which can affect (e.g., adversely affect) an accuracy of the EIS measurement. For example, the DC voltage or current can have a component at the specified EIS frequency (e.g., a component of a linearly increasing DC voltage projected onto the specified EIS frequency). This can result in a measured EIS value corresponding to a signal at the specified EIS frequency (e.g., an EIS excitation signal) in addition to a signal that is not at the specified EIS frequency (e.g., a charging signal or discharging signal). This can affect the accuracy of determination made using the measured EIS value. For example, if the SoC or temperature is determined using an EIS measurement having components from an EIS excitation signal in addition to a charging signal, the determined SoC or temperature may not be as accurate as if the EIS value only includes components related to the EIS excitation signal.

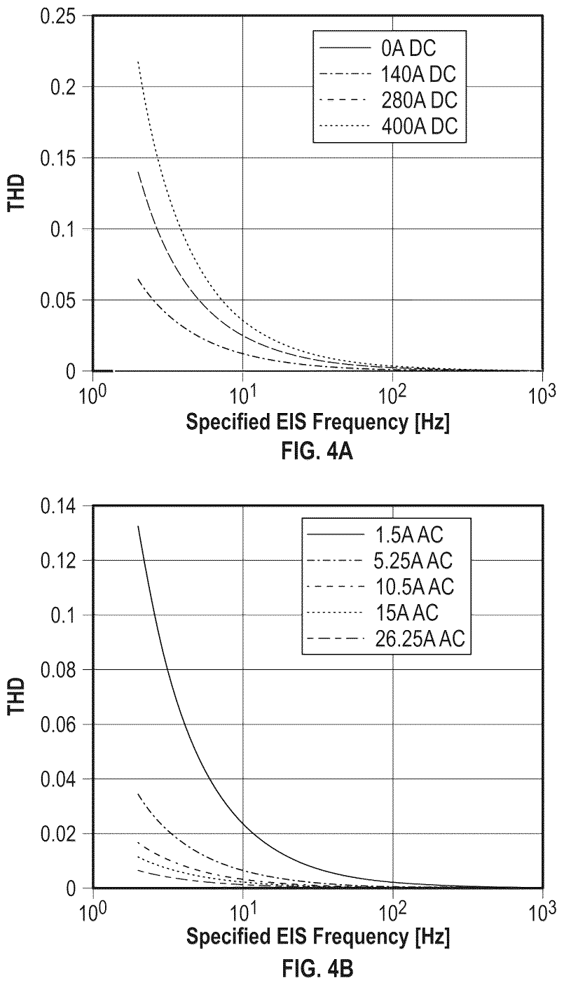

FIG. 4A and FIG. 4B show an example of the total harmonic distortion (THD) in an EIS voltage signal due to a DC current in a battery system. FIG. 4A and FIG. 4B show theoretical examples. THD can represent a ratio of an undesired signal component (e.g., the component of the EIS voltage caused by a non-steady state condition of the battery, the component of the EIS voltage caused by charging or discharging) to the desired signal component (e.g., the component of the EIS voltage due to the EIS excitation signal).

FIG. 4A and FIG. 4B show that the THD can increase (e.g., exponentially increase) as the specified EIS frequency decreases. FIG. 4A and FIG. 4B show that the THD can approach infinity as the specified EIS frequency approaches zero. FIG. 4A shows the THD resulting from the use of an EIS excitation signal with an amplitude of 1 amp in the presence of a DC charging current of 0 amps, 140 amps, 280 amps, and 400 amps. Because a larger charging current can produce a larger voltage ramp, the distortion introduced by a larger charging current can be greater than the distortion produced by a smaller charging current.

FIG. 4B shows the THD resulting from the use of an EIS excitation signal of a specified amplitude (e.g., 1.5 amps, 5.25 amps, 10.5 amps, 15 amps, and 26.25 amps) in the presence of a DC charging current of 400 amps. When the EIS excitation signal increases in amplitude, the component of the EIS voltage corresponding to the EIS excitation signal can increase in amplitude, which can reduce a THD for a specified charging current.

FIG. 4A and FIG. 4B show that the effects of a non-steady-state condition can be countered in part by increasing an amplitude of an EIS excitation signal or increasing an EIS measurement frequency. However, increasing an amplitude of the EIS excitation signal can be more expensive (e.g., due to more expensive hardware, more power required to produce the signal) or otherwise undesirable. Alternatively or additionally, some EIS properties may be benefitted by low frequency measurements. Accordingly, it can be desirable to reduce an effect of a non-steady-state condition on an EIS measurement.

An electrochemical impedance spectroscopy (EIS) measurement system can be configured to adjust for (e.g., correct for, reduce an effect of) a change in a direct current (DC) voltage value of an electrochemical cell in an energy storage system. The change in DC voltage level can have any cause, such as can include one or more of charging (e.g., the electrochemical cell voltage can increase during charging), discharging (e.g., the electrochemical cell voltage can decrease during discharging) relaxation after charging (e.g., the electrochemical cell voltage can relax to a steady state after being temporarily elevated by charging), or relaxation after discharging (e.g., the electrochemical cell voltage can relax to a steady state after being temporarily depressed by discharging). The EIS measurement system can include a current measurement device, a voltage measurement device, and processing circuitry.

The current measurement device can be arranged for measuring a current through the electrochemical cell (e.g., such as the current measurement IC 202). The voltage measurement device can be configured for measuring a voltage across the electrochemical cell, which can include being coupled across the electrochemical cell (e.g., the voltage measurement ICs 204). The processing circuitry can coupled to the current measurement device and/or the voltage measurement device. The processing circuitry can include any circuitry capable of implementing analog functions, digital functions, or both. In an example, the processing circuitry can include circuitry capable of executing instructions. The processing circuitry can be contained in a controller (e.g., the BMS controller 102). In an example, the processing circuitry can be distributed between one or more of the voltage measurement device (e.g., the signal processing and complex voltage determination blocks of the voltage measurement ICs 204), the current measurement device (e.g., the signal processing and complex voltage determination blocks of the current measurement IC 202), or the controller (e.g., the impedance calculation block of the BMS controller 102). Accordingly, a reference to “processing circuitry” does not require that the specified function be performed at a specific location within the EIS measurement system or that all functions performed by the processing circuitry are performed in one part of the EIS measurement system.

The processing circuitry can be configured to determine a representation of the DC voltage across the electrochemical cell. This can include determining a representation of the change in the steady state voltage of the electrochemical cell (e.g., a change in voltage not caused by the EIS excitation signal). A representation of the DC voltage across the electrochemical cell can indicate that the DC voltage across the electrochemical cell is changing, such as can be due to charging or discharging.

The processing circuitry can also be configured to determine an EIS voltage at a specified EIS frequency using the representation of the DC voltage across the electrochemical cell and the measured voltage across the electrochemical cell. For example, the processing circuitry can determine an unadjusted EIS voltage at the specified EIS frequency and then adjust the unadjusted EIS voltage using the representation of the DC voltage to determine the EIS voltage. In an example, the processing circuitry can determine the EIS voltage directly by considering the representation of the DC voltage and the voltage measured by the voltage measurement device. In an example, the processing circuitry can determine the EIS voltage and the representation of the DC voltage in the same operation, which can include determining the EIS voltage and the representation of the DC voltage simultaneously or at least partially concurrently. The DC voltage can be determined prior to determining the EIS voltage, after determining the EIS voltage, or simultaneously or at least partially concurrently with determining the EIS voltage.

The EIS measurement system can adjust for the change in the DC voltage value mathematically, such as by using a process to remove or reduce an effect the change in DC voltage value has on the determined EIS voltage. In an approach, this can include determining or estimating a mathematical description of the change in DC voltage value. Then, the component representation of the DC voltage projected onto the specified EIS frequency can be determined, and this value can be subtracted from an EIS voltage determined without accounting for the change in DC voltage.

For example, a curve fit can be performed on the measured voltage to estimate the DC voltage value (e.g., a curve fit on the voltage value of FIG. 3B, a curve fit on a series of digital samples of the voltage curve of FIG. 3B). The curve fit can include a linear curve fit (e.g., a slope and an intercept), a quadratic curve fit, (e.g., a quadratic term, a slope, and an intercept), a higher order curve fit, or a curve fit to any other function (e.g., a function other than a polynomial function). In an example where the type of curve fit is determined before an EIS measurement is made (e.g., the EIS measurement system is programmed or hard coded to use a quadratic curve fit), the specified curve fit can be projected onto EIS function (e.g., a sinusoid) prior to runtime in variable form. Then, during runtime, the EIS measurement system may only need to determine the curve fit (e.g., determine the values of variables in the curve fit) and apply these variables to the determined adjustment term. In an example, the curve fit can include any method of approximating a dataset with a mathematical function, such as can include a linear approximation.

The equations below show an example where a quadratic curve fit is used. The quadratic function can include a linear term, r (e.g., the slope), and a quadratic term, p. The intercept may not have an effect on the EIS measurement. Equation 1 shows a determination of the in-phase error (e.g., the real component) and Equation 2 shows a determination of the quadrature error (e.g., the imaginary component).

$${\int }_{0}^{N / f} ( f / N ) ( rx + {px}^{2} ) sin ( 2 π fx ) dx = - ( r + p * {t}_{conv} ) / ( 2 π f ) \qquad Equation 1$$

$${\int }_{0}^{N / f} ( f / N ) ( rx + {px}^{2} ) cos ( 2 π fx ) dx = p / ( 2 {π}^{2} {f}^{2} ) \qquad Equation 2$$

N can represent the number of periods in the sample (e.g., the collection of data points collected from the measured waveform), and f can represent the specified EIS frequency. The conversion time, t_conv, can represent the length of the EIS measurement relative the specified EIS frequency, and can be equal to N/f. The solutions to the integrals in equations 1 and 2 can represent the solution where N is a positive integer (e.g., 1, 2, 3, etc.).

The solutions to the integrals in equations 1 and 2 can be programmed into the processing circuitry. When the processing circuitry determines the quadratic curve fit of the voltage, the resulting terms can be plugged into the programmed correction equations and used to adjust the determined EIS voltage. For example, (r+p*t_{conv})/(2πf) can be added to the determined real component of the EIS voltage and p/(2π²f²) can be subtracted from the determined imaginary component of the EIS voltage.

In an example, a measured voltage value can be projected onto a function including a “relaxation” term or terms, which can at least partially account for a change in the DC voltage value. For example, the measured voltage (e.g., a time series of digital samples) can be projected onto equation 3.

$$( rx + {px}^{2} ) + A * sin ( 2 π fx ) \qquad Equation 3$$

Following the projection, the r and p terms can be discarded (e.g., because they correspond to an undesired signal), and the amplitude of the sinusoid, A, at the specified EI frequency can be retained as the EIS voltage. A similar process can be used to determine the quadrature component of the EIS voltage. In this example, determining a representation of the DC voltage and/or determining an EIS voltage at a specified EIS frequency can be performed in a single process or operation, and need not be separable steps. This can include considering a change in DC voltage across the electrochemical cell or considering a change in DC current through the electrochemical cell, even though the change in DC current and/or the change in DC voltage need not be determined or used in further operations (e.g., the relaxation term can account for the change in DC value, such as without directly determining a numerical value or using a determined value in further operations).

It should be appreciated that the examples described herein represent just a subset of the available techniques to determine an EIS voltage and adjust for the effect of a change in DC voltage. Other techniques apparent to one of skill in the art are also covered by this disclosure.

In an example, an EIS current value can be adjusted similarly to what is discussed above with respect to voltage. For example, a changing battery current (e.g., due to a changing charging or discharging current) can affect an EIS current measurement. Similar steps can be taken to adjust the EIS current measurement, alternatively or in addition to adjustments to the EIS voltage measurement.

In an example, to determine a representation of the DC voltage across the electrochemical cell includes to estimate a rate of change of the DC voltage across the electrochemical cell. This rate of change can include a linear rate of change (e.g., a slope), a quadratic rate of change (e.g., a slope term, a quadratic term, or both, as discussed above with respect to equations 1 and 2), or any other equation describing of a rate of change.

The processing circuitry can be configured to determine an EIS current at the specified EIS frequency, such as using the measured current through the electrochemical cell. The processing circuitry can also be configured to determine an EIS impedance of the electrochemical cell at the specified EIS frequency using the EIS voltage and the EIS current. This can include dividing the EIS voltage by the EIS current.

The processing circuitry can be configured to determine a representation of the DC current through the electrochemical cell. The representation of the DC current through the electrochemical cell can indicate that the DC current through the electrochemical cell is changing. Determining the EIS current at the specified EIS frequency can include using the representation of the DC current and the measured current through the electrochemical cell (e.g., as discussed above with respect to the voltage value). In an example the EIS voltage can be determined considering a rate of change in the DC voltage, the EIS current can be determined considering a rate of change in the DC current, or both.

The voltage measurement device can be configured to generate recurring (e.g., periodic) voltage measurements (e.g., a time series of digital samples). The processing circuitry can be configured to receive a plurality of recurring voltage measurements from the voltage measurement device. The processing circuitry can also be configured to determine, such as using the plurality of recurring voltage measurements an unadjusted EIS voltage comprising a component of the plurality of recurring voltage measurements at the specified EIS frequency, the representation of the DC voltage across the electrochemical cell, or both.

To determine the representation of the DC voltage across the electrochemical cell, the processing circuitry can be configured to determine a curve fit of the plurality of recurring voltage measurements (e.g., using a mathematical curve fit method). Alternatively or in addition, to determine the representation of the DC voltage across the electrochemical cell, the processing circuitry can be configured to perform one or more signal processing operations on the plurality of recurring voltage measurements (e.g., an analog filtering or smoothing step to remove a portion of the EIS excitation signal). The processing circuitry can be configured to determine a curve fit including determining one or more of a linear curve fit or a quadratic curve fit.

The processing circuitry can be configured to determine a voltage error component comprising a component of the representation of the DC voltage at the specified EIS frequency. The processing circuitry can be configured to determine the EIS voltage by subtracting the voltage error component from the unadjusted EIS voltage. For example, equations 1 and 2 can show the in-phase and quadrature-phase voltage error components, respectively, for a quadratic curve fit.

In an example, the processing circuitry can be configured such that the representation of the DC voltage includes a linear curve fit of the DC voltage across the electrochemical cell and the voltage error component includes the component of a line at the specified EIS frequency. In this example, the processing circuitry can be configured such that an in-phase portion of the voltage error component is proportional to a slope of the linear curve fit divided by an angular representation of the specified EIS frequency, the quadrature phase error component is zero, or both.

In an example, determining an EIS voltage at the specified EIS frequency can include projecting a time series representation of the voltage across the electrochemical cell onto: (1) a relaxation waveform configured to at least partially account for the DC voltage across the electrochemical cell, and (2) an EIS waveform having the specified EIS frequency (e.g., as discussed above with respect to equation 3).

In an example, the EIS measurement system can include an EIS signal source, which can be configured to generate a current signal through the electrochemical cell at a frequency including the specified EIS frequency. In an example, the EIS measurement system can include one or more electrochemical cells.

In an example, the processing circuitry can be distributed among the current measurement device, the voltage measurement device, and a controller, where the controller can be coupled to the current measurement device and the voltage measurement device.

In an example, the DC voltage ramp rate can be determined or estimated using the DC current value. For example, a look up table can be used to determine a representation of electrochemical cell voltage for a specified current value.

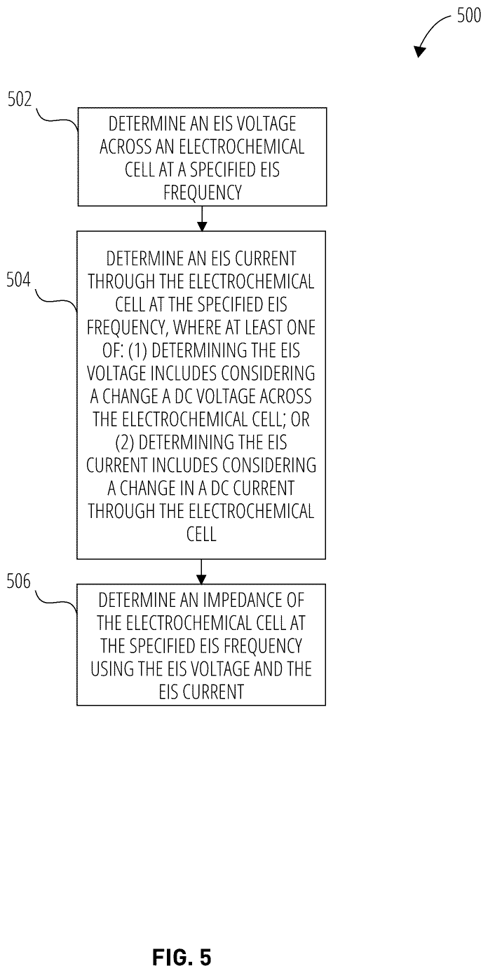

FIG. 5 shows an example of portions of a method 500 for operating an EIS measurement system. The method 500 can include a method for making an electrochemical impedance spectroscopy (EIS) measurement. At step 502 an EIS voltage across an electrochemical cell at a specified EIS frequency can be determined. At step 504 an EIS current through the electrochemical cell at the specified EIS frequency can be determined. One or more of: (1) determining the EIS voltage can include considering a change a DC voltage across the electrochemical cell; or (2) determining the EIS current can include considering a change in a DC current through the electrochemical cell. In an example, determining the EIS voltage includes considering a change a DC voltage across the electrochemical cell and determining the EIS current includes considering a change in a DC current through the electrochemical cell. At step 506, an impedance of the electrochemical cell at the specified EIS frequency can be determined using the EIS voltage and the EIS current.

The method can include determining an unadjusted EIS voltage across the electrochemical cell at the specified EIS frequency. The method can also include estimating a rate of change of the DC voltage across the electrochemical cell. Determining the EIS voltage across the electrochemical cell at the specified EIS frequency can include adjusting the unadjusted EIS voltage using the estimated rate of change of the DC voltage. Estimating the rate of change of the DC voltage across the electrochemical cell can include estimating a linear rate of change.

In an example, adjusting the unadjusted EIS voltage can include determining a voltage error component, which can correspond to the DC voltage projected onto the specified EIS frequency and subtracting the voltage error component from the unadjusted EIS voltage.

In an example, the EIS measurement is made during charging of the electrochemical cell. In this example, the change in the DC voltage across the electrochemical cell can be due at least in part to the charging of the electrochemical cell.

The shown order of steps is not intended to be a limitation on the order in which the steps are performed. In an example, two or more steps may be performed simultaneously or at least partially concurrently. Similar steps can be performed, alternatively or in addition, with respect to the EIS current.

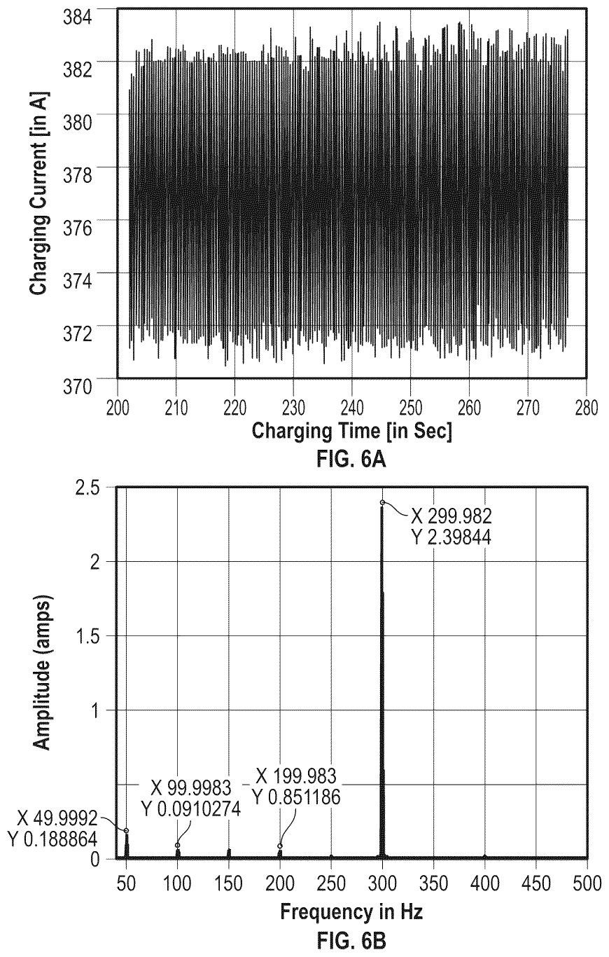

FIG. 6A shows an example of a graph in time showing laboratory recorded electrochemical cell charging current. FIG. 6B shows a frequency plot of the charging current of FIG. 6A. FIG. 6B shows that the charging current can have substantial components at 50, 100, 150, 200, and 300 hertz. These can correspond to the frequency of an electrical grid powering the charger (e.g., a 50 Hz) electrical grid and corresponding harmonics. FIG. 6A and FIG. 6B show that a “DC” charger can introduce AC signals in addition to the DC charging signal.

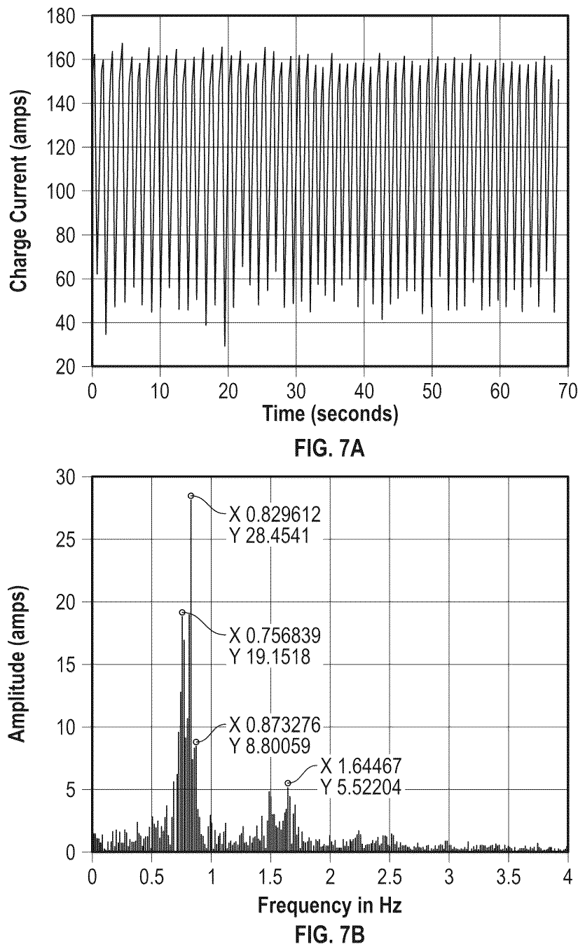

FIG. 7A shows an example of a graph in time showing laboratory recorded electrochemical cell charging current. FIG. 7B shows a frequency plot of the charging current of FIG. 7A. FIG. 7B shows that the charging current can have substantial components throughout the spectrum, such as particularly at low frequencies (e.g., below two hertz). The charger generating the charging signal of FIG. 7A can include a charger generating a waveform with substantial AC components. FIG. 7A and FIG. 7B show that a “DC” charger can be substantially composed of an AC signal, such as in addition to a DC charging signal.

The error in a determined EIS impedance measurement can be proportion to the ratio of a disturbance amplitude to a stimulus amplitude (e.g., excitation signal amplitude), such as can be shown in equation 4.

$$EIS Error \approx \frac{{I}_{disturbance}}{{I}_{stimulus}} \qquad Equation 4$$

The error in a determined EIS impedance can be the largest when the EIS impedance is at or near the frequency of one or more disturbance signals. However, an EIS error can be introduced by a disturbance signal that is not at or near the specified EIS frequency. It can be desirable to reduce or otherwise tailor an error introduced by an AC disturbance signal.

In an example, the processing circuitry can be configured to compare a determined EIS current to an expected current value. The processing circuitry can be configured to discard the measurement (e.g., the EIS current along with a corresponding EIS voltage (e.g., an EIS voltage corresponding to the EIS current, such as can include being measured simultaneously or at least partially concurrently) or EIS impedance (e.g., an EIS impedance determined using the EIS current)) in response to the comparison showing a difference above a specified current threshold.

The expected current value can include one or more of: (1) an average value from a plurality of prior EIS measurements; or (2) a predicted value determined at least in part using an EIS excitation magnitude. In the case of comparing the expected current value to an average from a plurality of previous EIS measurements, if the EIS excitation signal amplitude is not changing, it can be inferred that the measured EIS current should not change significantly either. Accordingly, discarding outlier measurements can help to improve an accuracy.

The EIS excitation signal source can generate an EIS excitation signal have a specified magnitude or a magnitude within a specified range. The excitation magnitude can be configurable or programmed. In an example, the excitation magnitude can be a specified, calibrated, or measured magnitude. If the measured EIS current differs from the expected current value by greater than the specified complex current value, this can indicate that a disturbance signal is affecting the EIS measurement, which can affect the accuracy of the EIS measurement. Accordingly, it can be desirable to discard the measurement and conduct another EIS measurement. For example, if the EIS excitation signal has an amplitude of 5 amps, it can be expected that the measured EIS current will be approximately 5 amps. The specified current threshold can be a fixed or adaptive threshold. The specified current threshold can have a specified value (e.g., 0.5 amps) or can be determined as a percentage of the expected current value (e.g., 10 percent of the expected current value).

In an example, the processing circuitry can be configured to handle the EIS voltage similarly to the EIS current discussed above. For example, the processing circuitry can be configured to compare a determined EIS voltage to an expected voltage value. The processing circuitry can be configured to discard the measurement in response to the comparison showing a difference above a specified voltage threshold. The processing circuitry can be configured to compare the EIS current to an expected current, the EIS voltage to an expected voltage value, or both. The expected voltage value can include one or more of: (1) an average value from a plurality of prior EIS measurements; or (2) a predicted value determined at least in part using an EIS excitation magnitude. In the case where the EIS excitation signal is a current signal, the predicted voltage value can be determine using the excitation amplitude and a predicted impedance of the electrochemical cell.

Alternatively or in addition to discarding measurements, multiple EIS measurements at a specified EIS frequency can be performed, and a central tendency (e.g., mean, median, mode) of the resulting EIS impedances can be determined. This central tendency can be more accurate or more likely to be accurate than a measurement in isolation. In an example, the phases of respective measurements can differ, such as can be due to a specified measurement phase or a random or pseudo-random measurement start time. For example, the EIS excitation signal can have a specified phase. The specified phase can be provided to the current measurement device or the voltage measurement device, however, in an example, the specified phase need not be provided.

A disturbance signal can also have a specified phase. In an example, when the phase of the EIS excitation signal is varied with respect to the phase of the disturbance signal, the resulting EIS measurement can also be affected. Varying the phase of the EIS measurements and determining a central tendency of multiple EIS measurements can reduce, adjust, or otherwise tailor the effect of the disturbance signal on the EIS measurement.

An electrochemical impedance spectroscopy (EIS) measurement system can be configured to adjust for an alternating current (AC) signal (e.g., a disturbance signal, a noise signal, a signal not due to the EIS excitation signal, etc.) of an electrochemical cell in an energy storage system, the EIS measurement system can include a current measurement device, which can be arranged for measuring a current through the electrochemical cell. The EIS measurement system can also include a voltage measurement device, which can be arranged to be coupled across the electrochemical cell, and can be configured for measuring a voltage across the electrochemical cell. The EIS measurement system can also include processing circuitry, which can be coupled to the current measurement device and the voltage measurement device and configured to determine an EIS impedance at a specified EIS frequency. This can include performing a first EIS impedance measurement using an EIS excitation signal having a first phase which can produce a first intermediate EIS impedance value. This can also include performing a second EIS impedance measurement using an EIS excitation signal having a second phase, wherein the first phase can differ from the second phase, which can produce a second intermediate EIS impedance value. Additionally, the processing circuitry can be configured to determine the EIS impedance, such as including by determining a central tendency of the first intermediate EIS impedance value and the second intermediate EIS impedance value.

Performing the first EIS impedance measurement and/or performing the second EIS impedance measurement each include one or more of: (1) performing an EIS voltage measurement at the specified EIS frequency to produce an EIS voltage; (2) performing an EIS current measurement at the specified EIS frequency to produce an EIS current; or (3) determining the EIS impedance using the EIS voltage and the EIS current.

In an example, the first phase and the second phase can differ by a specified phase value. For example, the processing circuitry can be configured to control the respective EIS excitation signals of the first EIS impedance measurement and the second EIS impedance measurement to differ by the specified phase value. In this example, the processing circuitry can use a timing controller (e.g., a clock) to keep track of the relative phases between EIS measurements.

In an example, the first phase and the second phase can differ by at least one of a random or pseudo-random (e.g., generated by a software based random number generator) phase value. The random or pseudo-random phase value can be due at least in part to a start time of the first EIS impedance measurement and the second EIS impedance measurement being one or more of random or pseudo-random. For example, the processing circuitry can be configured to start respective EIS measurements without regard for a phase. In this example, the respective phases of the measurements can be random to the unspecified nature of the start times (e.g., measurements can be performed back-to-back at the speed allowed by the EIS measurement system). In an example, the processing circuitry can operate to generate a random or pseudo-random start time, such as by delaying by a random or pseudo random time length each time a measurement is triggered (e.g., measurements can be performed back-to-back at the speed allowed by the EIS measurement system with the inclusion of a randomized or pseudo-randomized delay between measurements).

The processing circuitry can be configured to perform one or more additional EIS impedance measurements using EIS excitation signals having respective phases that can differ from the phases of the other ones of the EIS impedance measurements. In an example, three or more (e.g., three, four, five, 10, 15, etc.) EIS impedance measurements can be performed at the same specified EIS frequency. The phase of the excitation signal for one or more of the EIS impedance measurements can differ from the phase of the excitation signal of one or more of the other ones of the EIS impedance measurements. In an example, all of the EIS impedance measurements are made using a distinct phase.

The processing circuitry can be configured to perform a plurality of EIS impedance measurements, wherein respective phases of the EIS excitation signals used in the EIS impedance measurements can be substantially evenly distributed across 360 degrees of phase. For example, the EIS measurement system can perform four EIS impedance measurements spaced by approximately 90 degrees. In an example, the phases of the EIS excitation signals need not be evenly spaced.

The AC signal can be due at least in part to at least one of a charging signal received by the electrochemical cell (e.g., as shown and discussed with respect to FIG. 6A through FIG. 7B) or a discharging of the electrochemical cell to power a load (e.g., a traction motor load).

In an example, the AC signal can be due to a charging signal received by the electrochemical cell and the AC signal can have a frequency component that substantially matches a frequency of an AC power source powering the device producing the charging signal. The AC signal can also include frequency components that are multiples of the frequency of the AC power source (e.g., harmonics).

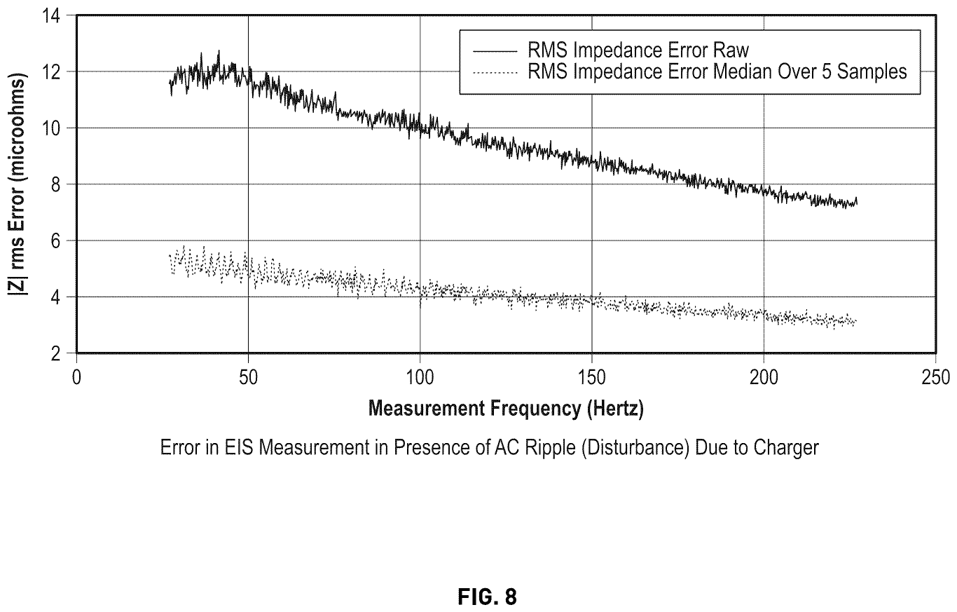

FIG. 8 shows a graph of an example of an error caused by a disturbance signal. FIG. 8 shows the error in an individual sample (e.g., the raw error) in addition to the error in an impedance determined using the median of 5 samples. FIG. 8 shows laboratory collected data of EIS measurements conducted on an electrochemical cell with disturbance harmonics of 0.8296 hertz (e.g., disturbance signals at 0.8296 hertz and integer multiples thereof). In the example of FIG. 8 shows that the median value consistently has a smaller error than the raw value. FIG. 8 shows that the error increases as the frequency decreases.

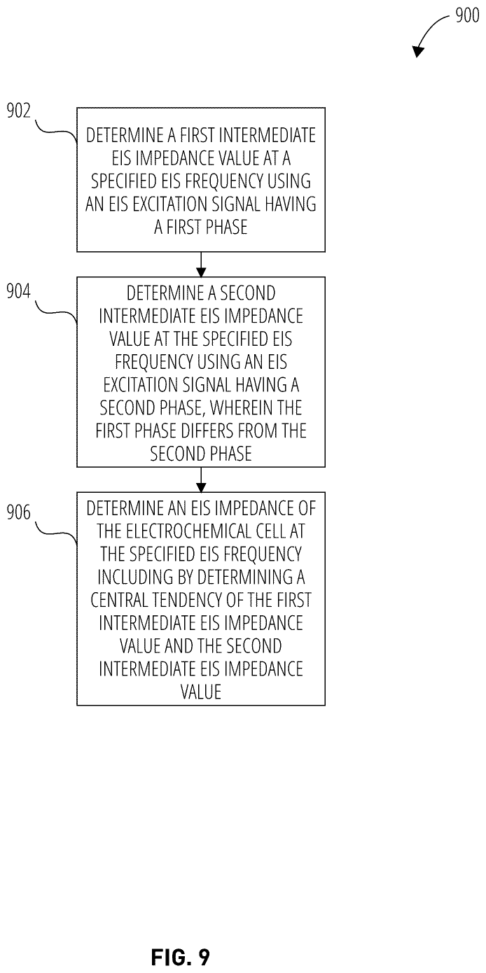

FIG. 9 shows an example of portions of a method 900 for operating a an EIS measurements system. The method 900 can include a method for making an electrochemical impedance spectroscopy (EIS) measurement of an electrochemical cell in an energy storage system. At step 902, a first intermediate EIS impedance value at a specified EIS frequency can be determined using an EIS excitation signal having a first phase.

At step 904 a second intermediate EIS impedance value at the specified EIS frequency can be determined using an EIS excitation signal having a second phase, wherein the first phase can differ from the second phase. Determining the first intermediate EIS impedance value and/or determining the second intermediate EIS impedance value can include one or more of: (1) performing an EIS voltage measurement at the specified EIS frequency to produce an EIS voltage; (2) performing an EIS current measurement at the specified EIS frequency to produce an EIS current; or (3) determining the EIS impedance using the EIS voltage and the EIS current.

At step 906, an EIS impedance of the electrochemical cell at the specified EIS frequency can be determined, optionally including by determining a central tendency of the first intermediate EIS impedance value and the second intermediate EIS impedance value.

In an example, the method 900 can include performing one or more additional EIS impedance measurements using EIS excitation signals having respective phases that can differ from the phases of the other ones of the EIS impedance measurements. The method can include determining a central tendency of all of the EIS impedance measurements.

The shown order of steps is not intended to be a limitation on the order in which the steps are performed. In an example, two or more steps may be performed simultaneously or at least partially concurrently.

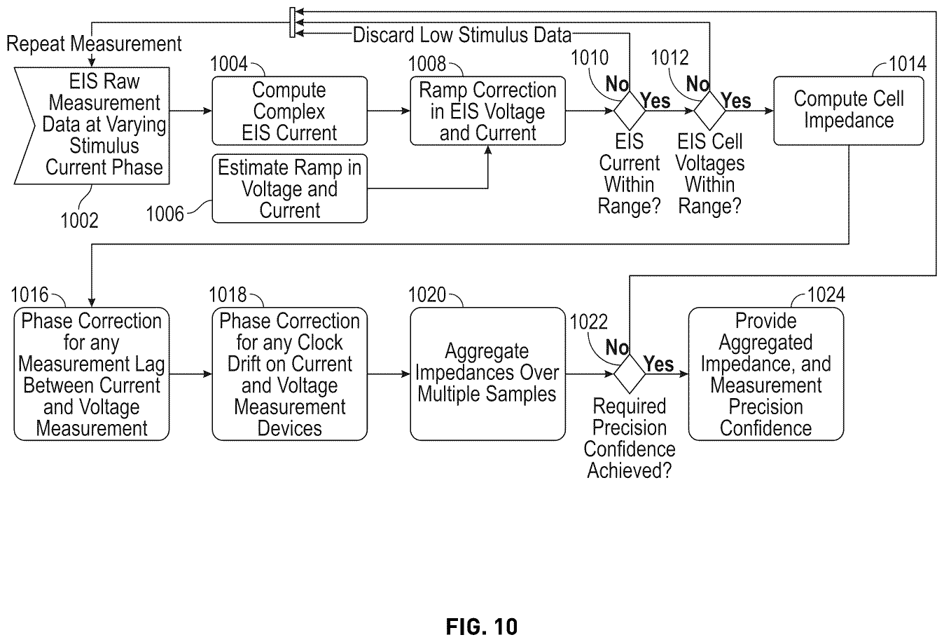

FIG. 10 shows an example of portions of a operational flow chart of an EIS measurement system. At block 1002, raw EIS measurement data can be obtained, which can include an EIS measurement corresponding to an EIS current (e.g., a voltage across a sense resistor), an EIS voltage measurement corresponding to an electrochemical cell, or both. At block 1004, an EIS current value can be determined, such as using the EIS measurement corresponding to the EIS current determined in block 1002.

At block 1006, the ramp rate (e.g., a linear and quadratic term) in the EIS current, EIS voltage, or both, can be determined. At block 1008, the EIS voltage, the EIS current, or both can be adjusted based on the determined ramp rate. Blocks 1006 and block 1008 can include or be replaced by blocks to perform any of the adjustments based on a non-steady-state condition discussed herein.

At block 1010, the EIS current can be compared to an expected current value, such as is discussed above. If the EIS current differs from the expected value by more than a specified current threshold, the measurement can be discarded and the operation can return to block 1002.

At block 1012, the EIS voltage can be compared to an expected voltage value, such as is discussed above. If the EIS voltage differs from the expected value by more than a specified voltage threshold, the measurement can be discarded and the operation can return to block 1002.

At block 1014, the electrochemical cell EIS impedance can be calculated, such as using the EIS current and EIS voltage.

At block 1016, a correction can be applied to adjust for a phase difference between the EIS current and EIS voltage values.

At block 1018, a correction can be applied to adjust for a clock drift in a measurement circuit (e.g., the voltage measurement device, the current measurement device).

At block 1020, a central tendency of two or more impedances can be determined. For example, the operation can go from block 1018 back to block 1002 while recording each determined impedance until a specified number of impedances have been collected.

At block 1022, a confidence level can be determined. For example, a standard deviation of the determined impedances divided by the number of samples can be determined. If the confidence level is below a specified confidence threshold, the operation can return to block 1002.

At block 1024, the EIS impedance (e.g., the central tendency of two or more samples) can be provided (e.g., provided to a user, provided to another circuit or system), optionally including the confidence level.

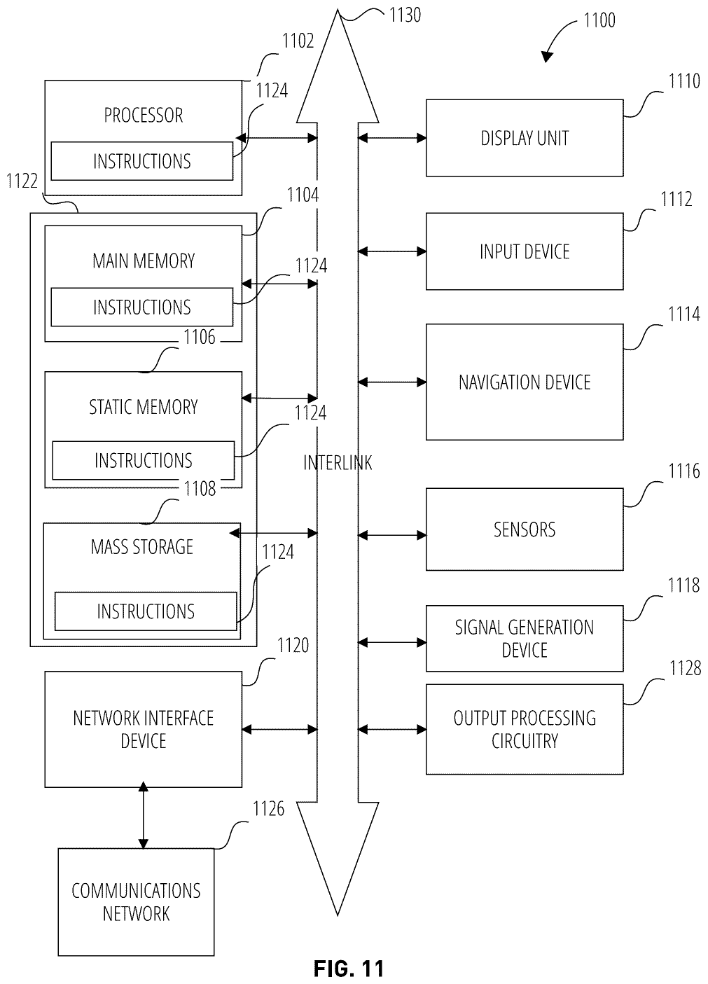

FIG. 11 illustrates a block diagram of an example machine 1100 upon which any one or more of the techniques (e.g., methodologies) discussed herein may be implemented. Examples, as described herein, may include, or may operate by, logic or a number of components, or mechanisms in the machine 1100. Circuitry (e.g., processing circuitry) is a collection of circuits implemented in tangible entities of the machine 1100 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 1100 follow.

In alternative examples, the machine 1100 may operate as a standalone device or may be connected (e.g., networked) to other machines. In a networked deployment, the machine 1100 may operate in the capacity of a server machine, a client machine, or both in server-client network environments. In an example, the machine 1100 may act as a peer machine in peer-to-peer (P2P) (or other distributed) network environment. The machine 1100 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 1100 may include a hardware processor 1102 (e.g., a central processing unit (CPU), a graphics processing unit (GPU), a hardware processor core, or any combination thereof), a main memory 1104, a static memory (e.g., memory or storage for firmware, microcode, a basic-input-output (BIOS), and mass storage 1108 (e.g., hard drives, tape drives, flash storage, or other block devices) some or all of which may communicate with each other via an interlink 1130 (e.g., bus). The machine 1100 may further include a display unit 1110, an alphanumeric input device 1112 (e.g., a keyboard), and a user interface (UI) navigation device 1114 (e.g., a mouse). In an example, the display unit 1110, input device 1112 and UI navigation device 1114 may be a touch screen display. The machine 1100 may additionally include a signal generation device 1118 (e.g., a speaker), a network interface device 1120, and one or more sensors 1116, such as a global positioning system (GPS) sensor, compass, accelerometer, or other sensor. The machine 1100 may include an output processing circuitry 1128, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 1102, the main memory 1104, the static memory 1106, or the mass storage 1108 may be, or include, a machine readable medium 1122 on which is stored one or more sets of data structures or instructions 1124 (e.g., software) embodying or utilized by any one or more of the techniques or functions described herein. The instructions 1124 may also reside, completely or at least partially, within any of registers of the processor 1102, the main memory 1104, the static memory 1106, or the mass storage 1108 during execution thereof by the machine 1100. In an example, one or any combination of the hardware processor 1102, the main memory 1104, the static memory 1106, or the mass storage 1108 may constitute the machine readable media 1122. While the machine readable medium 1122 is illustrated as a single medium, the term “machine readable medium” may include a single medium or multiple media (e.g., a centralized or distributed database, and/or associated caches and servers) configured to store the one or more instructions 1124.

The term “machine readable medium” may include any medium that is capable of storing, encoding, or carrying instructions for execution by the machine 1100 and that cause the machine 1100 to perform any one or more of the techniques of the present disclosure, or that is capable of storing, encoding or carrying data structures used by or associated with such instructions. Non-limiting machine readable medium examples may include solid-state memories, optical media, magnetic media, and signals (e.g., radio frequency signals, other photon based signals, sound signals, etc.). In an example, a non-transitory machine readable medium comprises a machine readable medium with a plurality of particles having invariant (e.g., rest) mass, and thus are compositions of matter. Accordingly, non-transitory machine-readable media are machine readable media that do not include transitory propagating signals. Specific examples of non-transitory machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

In an example, information stored or otherwise provided on the machine readable medium 1122 may be representative of the instructions 1124, such as instructions 1124 themselves or a format from which the instructions 1124 may be derived. This format from which the instructions 1124 may be derived may include source code, encoded instructions (e.g., in compressed or encrypted form), packaged instructions (e.g., split into multiple packages), or the like. The information representative of the instructions 1124 in the machine readable medium 1122 may be processed by processing circuitry into the instructions to implement any of the operations discussed herein. For example, deriving the instructions 1124 from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 1124.

In an example, the derivation of the instructions 1124 may include assembly, compilation, or interpretation of the information (e.g., by the processing circuitry) to create the instructions 1124 from some intermediate or preprocessed format provided by the machine readable medium 1122. The information, when provided in multiple parts, may be combined, unpacked, and modified to create the instructions 1124. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 1124 may be further transmitted or received over a communications network 1126 using a transmission medium via the network interface device 1120 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), LoRa/LoRaWAN, or satellite communication networks, mobile telephone networks (e.g., cellular networks such as those complying with 3G, 4G LTE/LTE-A, or 5G standards), Plain Old Telephone (POTS) networks, and wireless data networks (e.g., Institute of Electrical and Electronics Engineers (IEEE) 802.11 family of standards known as Wi-Fi®, IEEE 802.15.4 family of standards, peer-to-peer (P2P) networks, among others. In an example, the network interface device 1120 may include one or more physical jacks (e.g., Ethernet, coaxial, or phone jacks) or one or more antennas to connect to the communications network 1126. In an example, the network interface device 1120 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 1100, and includes digital or analog communications signals or other intangible medium to facilitate communication of such software. A transmission medium is a machine-readable medium.

The following, non-limiting examples, detail certain aspects of the present subject matter to solve the challenges and provide the benefits discussed herein, among others.

### Examples

Example 1 is an electrochemical impedance spectroscopy (EIS) measurement system to adjust for a change in a direct current (DC) voltage value of an electrochemical cell in an energy storage system, the EIS measurement system comprising: a current measurement device, arranged for measuring a current through the electrochemical cell; a voltage measurement device, arranged to be coupled across the electrochemical cell, for measuring a voltage across the electrochemical cell; and processing circuitry, coupled to the current measurement device and the voltage measurement device and configured to: determine a representation of the DC voltage across the electrochemical cell, wherein the representation of the DC voltage across the electrochemical cell indicates that the DC voltage across the electrochemical cell is changing; and determine an EIS voltage at a specified EIS frequency using the representation of the DC voltage across the electrochemical cell and the measured voltage across the electrochemical cell.

In Example 2, the subject matter of Example 1 optionally includes wherein to determine a representation of the DC voltage across the electrochemical cell includes to estimate a rate of change of the DC voltage across the electrochemical cell.

In Example 3, the subject matter of any one or more of Examples 1-2 optionally include wherein the processing circuitry is configured to: determine an EIS current at the specified EIS frequency using the measured current through the electrochemical cell; and determine an EIS impedance of the electrochemical cell at the specified EIS frequency using the EIS voltage and the EIS current.

In Example 4, the subject matter of Example 3 optionally includes wherein: the processing circuitry is configured to determine a representation of the DC current through the electrochemical cell, wherein the representation of the DC current through the electrochemical cell indicates that the DC current through the electrochemical cell is changing; and determining the EIS current at the specified EIS frequency includes using the representation of the DC current and the measured current through the electrochemical cell.

In Example 5, the subject matter of any one or more of Examples 1˜4 optionally include wherein: the voltage measurement device is configured to generate recurring voltage measurements; and the processing circuitry is configured to: receive a plurality of recurring voltage measurements from the voltage measurement device; and determine, using the plurality of recurring voltage measurements: an unadjusted EIS voltage comprising a component of the plurality of recurring voltage measurements at the specified EIS frequency; and the representation of the DC voltage across the electrochemical cell.

In Example 6, the subject matter of Example 5 optionally includes wherein to determine the representation of the DC voltage across the electrochemical cell, the processing circuitry is configured to: determine a curve fit of the plurality of recurring voltage measurements.

In Example 7, the subject matter of Example 6 optionally includes wherein the processing circuitry is configured to determine a curve fit including determining at least one of a linear curve fit or a quadratic curve fit.

In Example 8, the subject matter of any one or more of Examples 5-7 optionally include wherein to determine the representation of the DC voltage across the electrochemical cell, the processing circuitry is configured to: perform one or more signal processing operations on the plurality of recurring voltage measurements.

In Example 9, the subject matter of any one or more of Examples 5-8 optionally include wherein the processing circuitry is configured to: determine a voltage error component comprising a component of the representation of the DC voltage at the specified EIS frequency; and determine the EIS voltage by subtracting the voltage error component from the unadjusted EIS voltage.

In Example 10, the subject matter of Example 9 optionally includes wherein the processing circuitry is configured such that: the representation of the DC voltage includes a linear curve fit of the DC voltage across the electrochemical cell; and the voltage error component includes the component of a line at the specified EIS frequency.

In Example 11, the subject matter of Example 10 optionally includes wherein the processing circuitry is configured such that: an in-phase portion of the voltage error component is proportional to a slope of the linear curve fit divided by an angular representation of the specified EIS frequency; and a quadrature-phase portion of the voltage error component is zero.

In Example 12, the subject matter of any one or more of Examples 1-11 optionally include) an EIS waveform having the specified EIS frequency.

In Example 13, the subject matter of any one or more of Examples 1-12 optionally include an EIS signal source, configured to generate a current signal through the electrochemical cell at a frequency including the specified EIS frequency.

In Example 14, the subject matter of any one or more of Examples 1-13 optionally include wherein the processing circuitry is distributed among the current measurement device, the voltage measurement device, and a controller, wherein the controller is coupled to the current measurement device and the voltage measurement device.

Example 15 is a method for making an electrochemical impedance spectroscopy (EIS) measurement, the method comprising: determining an EIS voltage across an electrochemical cell at a specified EIS frequency; determining an EIS current through the electrochemical cell at the specified EIS frequency, wherein at least one of: (1) determining the EIS voltage includes considering a change a DC voltage across the electrochemical cell; or (2) determining the EIS current includes considering a change in a DC current through the electrochemical cell; and determining an impedance of the electrochemical cell at the specified EIS frequency using the EIS voltage and the EIS current.

In Example 16, the subject matter of Example 15 optionally includes determining an unadjusted EIS voltage across the electrochemical cell at the specified EIS frequency; estimating a rate of change of the DC voltage across the electrochemical cell; and wherein determining the EIS voltage across the electrochemical cell at the specified EIS frequency includes adjusting the unadjusted EIS voltage using the estimated rate of change of the DC voltage.

In Example 17, the subject matter of Example 16 optionally includes wherein: estimating the rate of change of the DC voltage across the electrochemical cell includes estimating a linear rate of change.

In Example 18, the subject matter of Example 17 optionally includes wherein adjusting the unadjusted EIS voltage includes: determining a voltage error component corresponding to the DC voltage projected onto the specified EIS frequency; and subtracting the voltage error component from the unadjusted EIS voltage.

In Example 19, the subject matter of any one or more of Examples 15-18 optionally include wherein: the EIS measurement is made during charging of the electrochemical cell; and the change in the DC voltage across the electrochemical cell is due at least in part to the charging of the electrochemical cell.

Example 20 is an electrochemical impedance spectroscopy (EIS) measurement system to adjust for a change in a direct current (DC) voltage value of an electrochemical cell in an energy storage system, the EIS measurement system comprising: a current measurement device, arranged for measuring a current through the electrochemical cell; a voltage measurement device, arranged to be coupled across the electrochemical cell, for measuring a voltage across the electrochemical cell; and processing circuitry, coupled to the current measurement device and the voltage measurement device and configured to: determine a representation of the DC current through the electrochemical cell, wherein the representation of the DC current through the electrochemical cell indicates that the DC current through the electrochemical cell is changing; and determine an EIS current at a specified EIS frequency using the representation of the DC current through the electrochemical cell and the measured current through the electrochemical cell.

Example 21 is an electrochemical impedance spectroscopy (EIS) measurement system to adjust for an alternating current (AC) signal of an electrochemical cell in an energy storage system, the EIS measurement system comprising: a current measurement device, arranged for measuring a current through the electrochemical cell; a voltage measurement device, arranged to be coupled across the electrochemical cell, for measuring a voltage across the electrochemical cell; and processing circuitry, coupled to the current measurement device and the voltage measurement device and configured to: determine an EIS impedance at a specified EIS frequency, including: performing a first EIS impedance measurement using an EIS excitation signal having a first phase to produce a first intermediate EIS impedance value; performing a second EIS impedance measurement using an EIS excitation signal having a second phase, wherein the first phase differs from the second phase, to produce a second intermediate EIS impedance value; and determining the EIS impedance including by determining a central tendency of the first intermediate EIS impedance value and the second intermediate EIS impedance value.

In Example 22, the subject matter of Example 21 optionally includes wherein to perform the first EIS impedance measurement and to perform the second EIS impedance measurement each include: performing an EIS voltage measurement at the specified EIS frequency to produce an EIS voltage; performing an EIS current measurement at the specified EIS frequency to produce an EIS current; and determining the EIS impedance using the EIS voltage and the EIS current.

In Example 23, the subject matter of Example 22 optionally includes wherein the processing circuitry is configured to: compare the EIS current to an expected current value; and discard the measurement in response to the comparison showing a difference above a specified current threshold.

In Example 24, the subject matter of Example 23 optionally includes wherein the processing circuitry is configured to: compare the EIS voltage to an expected voltage value; and discard the measurement in response to the comparison showing a difference above a specified voltage threshold.

In Example 25, the subject matter of any one or more of Examples 23-24 optionally include) a predicted value determined at least in part using an EIS excitation magnitude.

In Example 26, the subject matter of any one or more of Examples 21-25 optionally include wherein the processing circuitry is configured to perform one or more additional EIS impedance measurements using EIS excitation signals having respective phases that differ from the phases of the other ones of the EIS impedance measurements.

In Example 27, the subject matter of Example 26 optionally includes degrees of phase.

In Example 28, the subject matter of any one or more of Examples 21-27 optionally include wherein the first phase and the second phase differ by a specified phase value, wherein the processing circuitry is configured to control the respective EIS excitation signals of the first EIS impedance measurement and the second EIS impedance measurement to differ by the specified phase value.

In Example 29, the subject matter of any one or more of Examples 21-28 optionally include wherein the first phase and the second phase differ by at least one of a random or pseudo-random phase value, wherein the random or pseudo-random phase value is due at least in part to a start time of the first EIS impedance measurement and the second EIS impedance measurement being at least one of random or pseudo-random.

In Example 30, the subject matter of any one or more of Examples 21-29 optionally include wherein the AC signal is due at least in part to at least one of a charging signal received by the electrochemical cell or a discharging of the electrochemical cell to power a load.

In Example 31, the subject matter of Example 30 optionally includes wherein: the AC signal is due to a charging signal received by the electrochemical cell; and the AC signal has a frequency component that substantially matches a frequency of an AC power source powering the device producing the charging signal.

Example 32 is a method for making an electrochemical impedance spectroscopy (EIS) measurement of an electrochemical cell in an energy storage system, the method comprising: determining a first intermediate EIS impedance value at a specified EIS frequency using an EIS excitation signal having a first phase; determining a second intermediate EIS impedance value at the specified EIS frequency using an EIS excitation signal having a second phase, wherein the first phase differs from the second phase; and determining an EIS impedance of the electrochemical cell at the specified EIS frequency including by determining a central tendency of the first intermediate EIS impedance value and the second intermediate EIS impedance value.

In Example 33, the subject matter of Example 32 optionally includes wherein determining the first intermediate EIS impedance value and determining the second intermediate EIS impedance value each include: performing an EIS voltage measurement at the specified EIS frequency to produce an EIS voltage; performing an EIS current measurement at the specified EIS frequency to produce an EIS current; and determining the EIS impedance using the EIS voltage and the EIS current.

In Example 34, the subject matter of any one or more of Examples 32-33 optionally include performing one or more additional EIS impedance measurements using EIS excitation signals having respective phases that differ from the phases of the other ones of the EIS impedance measurements.

In Example 35, the subject matter of any one or more of Examples 32-34 optionally include controlling the first phase and the second phase using a timing controller to produce a specified phase difference between the first phase and the second phase.

In Example 36, the subject matter of any one or more of Examples 32-35 optionally include at least one of randomizing or pseudo-randomizing a start time of the first EIS impedance measurement and the second EIS impedance measurement to produce a random or pseudo-random phase difference between the first phase and the second phase.

Example 37 is an electrochemical impedance spectroscopy (EIS) measurement system to adjust for an alternating current (AC) signal of an electrochemical cell in an energy storage system, the EIS measurement system comprising: a current measurement device, arranged for measuring a current through the electrochemical cell; a voltage measurement device, arranged to be coupled across the electrochemical cell, for measuring a voltage across the electrochemical cell; and processing circuitry, coupled to the current measurement device and the voltage measurement device and configured to: perform an EIS current measurement at a specified EIS frequency to produce an EIS current; compare the EIS current to an expected current value; and discard the EIS current measurement in response to the comparison showing a difference above a specified current threshold.

In Example 38, the subject matter of Example 37 optionally includes wherein the processing circuitry is configured to: perform an EIS voltage measurement at the specified EIS frequency to produce an EIS voltage; compare the EIS voltage to an expected current value; and discard the EIS voltage measurement in response to the comparison showing a difference above a specified voltage threshold.

In Example 39, the subject matter of Example 38 optionally includes wherein the processing circuitry is configured to: determine an EIS impedance at the specified EIS frequency using the EIS current and the EIS voltage in response to the EIS current and the EIS voltage being retained.

In Example 40, the subject matter of Example 39 optionally includes wherein: the EIS current measurement and the EIS voltage measurement are performed using an EIS excitation signal having a first phase; and the processing circuitry is configured to: determine a second EIS impedance at the specified EIS frequency using EIS current and EIS voltage values determined using an EIS excitation signal having a second phase, wherein the first phase differs from the second phase; and determine an adjusted EIS impedance including by determining a central tendency of the EIS impedance and the second EIS impedance.

Example 41 is at least one machine-readable medium including instructions that, when executed by processing circuitry, cause the processing circuitry to perform operations to implement of any of Examples 1-40.

Example 42 is an apparatus comprising means to implement of any of Examples 1-40.

Example 43 is a system to implement of any of Examples 1-40.

Example 44 is a method to implement of any of Examples 1-40.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific examples that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the terms “or” and “and/or” are used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5). Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4).

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like.

Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other examples may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the examples should be determined with reference to the appended claims, along with the full scope of equivalents to which such claims are entitled.

What is claimed is:

1. An electrochemical impedance spectroscopy (EIS) measurement system to adjust for an alternating current (AC) signal of an electrochemical cell in an energy storage system, the EIS measurement system comprising:
a current measurement device, arranged for measuring a current through the electrochemical cell;
a voltage measurement device, arranged to be coupled across the electrochemical cell, for measuring a voltage across the electrochemical cell; and
processing circuitry, coupled to the current measurement device and the voltage measurement device and configured to:
determine an EIS impedance at a specified EIS frequency, including:
performing a first EIS impedance measurement using an EIS excitation signal having a first phase to produce a first intermediate EIS impedance value;
performing a second EIS impedance measurement using an EIS excitation signal having a second phase, wherein the first phase differs from the second phase, to produce a second intermediate EIS impedance value; and
determining the EIS impedance including by determining a central tendency of the first intermediate EIS impedance value and the second intermediate EIS impedance value.

2. The EIS measurement system of claim 1, wherein to perform the first EIS impedance measurement and to perform the second EIS impedance measurement each include:
performing an EIS voltage measurement at the specified EIS frequency to produce an EIS voltage;
performing an EIS current measurement at the specified EIS frequency to produce an EIS current; and
determining the EIS impedance using the EIS voltage and the EIS current.

3. The EIS measurement system of claim 2, wherein the processing circuitry is configured to:
compare the EIS current to an expected current value; and
discard the measurement in response to the comparison showing a difference above a specified current threshold.

4. The EIS measurement system of claim 3, wherein the processing circuitry is configured to:
compare the EIS voltage to an expected voltage value; and
discard the measurement in response to the comparison showing a difference above a specified voltage threshold.

5. The EIS measurement system of claim 3, wherein the expected current value includes at least one of: (1) an average value from a plurality of prior EIS measurements; or (2) a predicted value determined at least in part using an EIS excitation magnitude.

6. The EIS measurement system of claim 1, wherein the processing circuitry is configured to perform one or more additional EIS impedance measurements using EIS excitation signals having respective phases that differ from the phases of the other ones of the EIS impedance measurements.

7. The EIS measurement system of claim 6, wherein the processing circuitry is configured to perform a plurality of EIS impedance measurements, wherein respective phases of the EIS excitation signals used in the EIS impedance measurements are substantially evenly distributed across 360 degrees of phase.

8. The EIS measurement system of claim 1, wherein the first phase and the second phase differ by a specified phase value, wherein the processing circuitry is configured to control the respective EIS excitation signals of the first EIS impedance measurement and the second EIS impedance measurement to differ by the specified phase value.

9. The EIS measurement system of claim 1, wherein the first phase and the second phase differ by at least one of a random or pseudo-random phase value, wherein the random or pseudo-random phase value is due at least in part to a start time of the first EIS impedance measurement and the second EIS impedance measurement being at least one of random or pseudo-random.

10. The EIS measurement system of claim 1, wherein the AC signal is due at least in part to at least one of a charging signal received by the electrochemical cell or a discharging of the electrochemical cell to power a load.

11. The EIS measurement system of claim 10, wherein:
the AC signal is due to a charging signal received by the electrochemical cell; and
the AC signal has a frequency component that substantially matches a frequency of an AC power source powering the device producing the charging signal.

12. A method for making an electrochemical impedance spectroscopy (EIS) measurement of an electrochemical cell in an energy storage system, the method comprising:
determining a first intermediate EIS impedance value at a specified EIS frequency using an EIS excitation signal having a first phase;
determining a second intermediate EIS impedance value at the specified EIS frequency using an EIS excitation signal having a second phase, wherein the first phase differs from the second phase; and
determining an EIS impedance of the electrochemical cell at the specified EIS frequency including by determining a central tendency of the first intermediate EIS impedance value and the second intermediate EIS impedance value.

13. The method of claim 12, wherein determining the first intermediate EIS impedance value and determining the second intermediate EIS impedance value each include:
performing an EIS voltage measurement at the specified EIS frequency to produce an EIS voltage;
performing an EIS current measurement at the specified EIS frequency to produce an EIS current; and
determining the EIS impedance using the EIS voltage and the EIS current.

14. The method of claim 12, comprising:
performing one or more additional EIS impedance measurements using EIS excitation signals having respective phases that differ from the phases of the other ones of the EIS impedance measurements.

15. The method of claim 12, comprising:
controlling the first phase and the second phase using a timing controller to produce a specified phase difference between the first phase and the second phase.

16. The method of claim 12, comprising:
at least one of randomizing or pseudo-randomizing a start time of the first EIS impedance measurement and the second EIS impedance measurement to produce a random or pseudo-random phase difference between the first phase and the second phase.

17. An electrochemical impedance spectroscopy (EIS) measurement system to adjust for an alternating current (AC) signal of an electrochemical cell in an energy storage system, the EIS measurement system comprising:
a current measurement device, arranged for measuring a current through the electrochemical cell;
a voltage measurement device, arranged to be coupled across the electrochemical cell, for measuring a voltage across the electrochemical cell; and
processing circuitry, coupled to the current measurement device and the voltage measurement device and configured to:
perform an EIS current measurement at a specified EIS frequency to produce an EIS current;
compare the EIS current to an expected current value; and
discard the EIS current measurement in response to the comparison showing a difference above a specified current threshold.

18. The EIS measurement system of claim 17, wherein the processing circuitry is configured to:
perform an EIS voltage measurement at the specified EIS frequency to produce an EIS voltage;
compare the EIS voltage to an expected current value; and
discard the EIS voltage measurement in response to the comparison showing a difference above a specified voltage threshold.

19. The EIS measurement system of claim 18, wherein the processing circuitry is configured to:
determine an EIS impedance at the specified EIS frequency using the EIS current and the EIS voltage in response to the EIS current and the EIS voltage being retained.

20. The EIS measurement system of claim 19, wherein:
the EIS current measurement and the EIS voltage measurement are performed using an EIS excitation signal having a first phase; and
the processing circuitry is configured to:
determine a second EIS impedance at the specified EIS frequency using EIS current and EIS voltage values determined using an EIS excitation signal having a second phase, wherein the first phase differs from the second phase; and
determine an adjusted EIS impedance including by determining a central tendency of the EIS impedance and the second EIS impedance.
